(19) United States
(12) Patent Application Publication
(10) Pub. No.: US 2019/0238082 A1
(43) Pub. Date: Aug. 1, 2019

(54) Appliance With Load Sensing Electrical Circuit

(71) Applicant: Hamilton Beach Brands, Inc., Glen Allen, VA (US)

(72) Inventors: Jie Zhao, Midlothian, VA (US); Larry Olson, Montpelier, VA (US)

(21) Appl. No.: 15/885,264

(22) Filed: Jan. 31, 2018

(51) Int. Cl. H02P 29/02; H02H 7/085; H02H 1/00; G01R 31/34; G01R 19/165; F04D 15/02

(52) U.S. Cl. CPC H02P 29/02; H02H 7/085; F04D 15/0281; G01R 31/343; G01R 19/16576; H02H 1/0007

(57) ABSTRACT

An appliance comprises an electric motor, a resistor or an inductor in electrical series with the motor, and a controller. The controller activates the motor, detects a voltage across the resistor or inductor while the motor is activated, and deactivates the motor or changes an amount of electric power supplied to the motor in response to a change in the detected voltage.

### BACKGROUND OF THE DISCLOSURE

The present disclosure relates generally to small appliances, and more particularly to small appliances having a motor that is activated and deactivated during operation of the appliance.

Various types of small appliances use motors (DC or AC) to perform actions. Such motors need to be activated and deactivated at the correct times during operation of an appliance. Typically, a motor will be activated at the beginning of an operating cycle of an appliance (e.g., at the beginning of a brew cycle of a coffee maker or at the beginning of a grind cycle of a coffee grinder). It is often more difficult to determine the correct time to deactivate a motor in an appliance. For example, in a coffee maker it is necessary to deactivate the motor that drives the water pump when the water tank is empty or when the appropriate amount of water has been pumped. Conventional coffee makers use a temperature sensor in the water tank in communication with a controller to monitor the temperature in the water tank. The temperature in the water tank decreases slowly while the water tank is emptying and decreases faster when the water level has dropped enough that the temperature sensor is exposed. The controller will deactivate the motor when the temperature has dropped by a predetermined percentage or amount. The temperature data is noisy, making it difficult to accurately gauge when the water tank is empty and therefore that the motor driving the water pump should be deactivated. Running the motor too little may result in a smaller-than-desired amount of coffee brewed, while running the pump too much may cause overheating or pump failure.

It has heretofore not been discovered how to create an appliance having a motor that is activated and deactivated during operation of the appliance with a mechanism for accurately timing the deactivation of the motor. The appliance of the following disclosure overcomes at least one of the above-described disadvantages of conventional appliances.

### BRIEF SUMMARY OF THE DISCLOSURE

An appliance is disclosed herein. In one embodiment of the subject device, an appliance comprises an electric motor, a resistor or an inductor in electrical series with the motor, and a controller. The controller activates the motor, detects a voltage across the resistor or inductor while the motor is activated, and deactivates the motor or changes an amount of electric power supplied to the motor in response to a change in the detected voltage.

The resistor or the inductor may be selected such that a ratio of an impedance of the resistor or the inductor to an impedance of the motor is less than 0.4.

The motor may comprise a direct current (DC) motor, and the resistor or inductor may comprise a resistor.

The motor may comprise an alternating current (AC) motor, and the resistor or inductor may comprise an inductor. The inductor may comprise a primary coil of a transformer.

The appliance may comprise a coffeemaker and the motor may drive a water pump to move water or an air pump to pump air to displace water.

The appliance may comprise a coffee grinder and the motor rotate one or more grinding wheels or blades.

The controller may deactivate the motor or change the amount of electric power supplied to the motor if the change in the detected voltage exceeds a predetermined threshold percentage.

The controller may deactivate the motor or change the amount of electric power supplied to the motor if the change in the detected voltage exceeds a predetermined threshold amount.

The controller may deactivate the motor or change the amount of electric power supplied to the motor if the detected voltage is less than or greater than a predetermined threshold voltage.

The controller may deactivate the motor or change the amount of electric power supplied to the motor if the change in the detected voltage matches a predetermined pattern.

In alternative embodiments of the present disclosure, a method of controlling an electric motor in an appliance comprises activating an electric motor, detecting a voltage across a resistor or an inductor in electrical series with the motor while the motor is activated, and deactivating the motor in response to a decrease in the detected voltage.

In alternative embodiments of the present disclosure, a method of sensing motor load and controlling an electric motor accordingly comprises activating an electric motor, detecting a voltage across a resistor or an inductor in electrical series with the motor while the motor is activated, and deactivating the motor or changing the amount of electric power supplied to the motor in response to a change in the detected voltage.

### BRIEF DESCRIPTION OF THE SEVERAL VIEWS OF THE DRAWINGS

The foregoing summary, as well as the following detailed description of the disclosure, will be better understood when read in conjunction with the appended drawings. For the purpose of illustrating the disclosure, there are shown in the drawings embodiments which are presently preferred. It should be understood, however, that the disclosure is not limited to the precise arrangements and instrumentalities shown. In the drawings:

FIG. 1 is a block diagram of a small appliance, according to one embodiment of the present disclosure.

FIG. 2 is a simplified electrical circuit diagram for a load-sensing circuit to be used in a small appliance, according to one embodiment of the present disclosure.

### DETAILED DESCRIPTION OF THE DISCLOSURE

Certain terminology is used in the following description for convenience only and is not limiting. The words “lower,” “bottom,” “upper,” and “top” designate directions in the drawings to which reference is made. The words “inwardly,” “outwardly,” “upwardly” and “downwardly” refer to directions toward and away from, respectively, the geometric center of the device, and designated parts thereof, in accordance with the present disclosure. Unless specifically set forth herein, the terms “a,” “an” and “the” are not limited to one element, but instead should be read as meaning “at least one.” The terminology includes the words noted above, derivatives thereof and words of similar import.

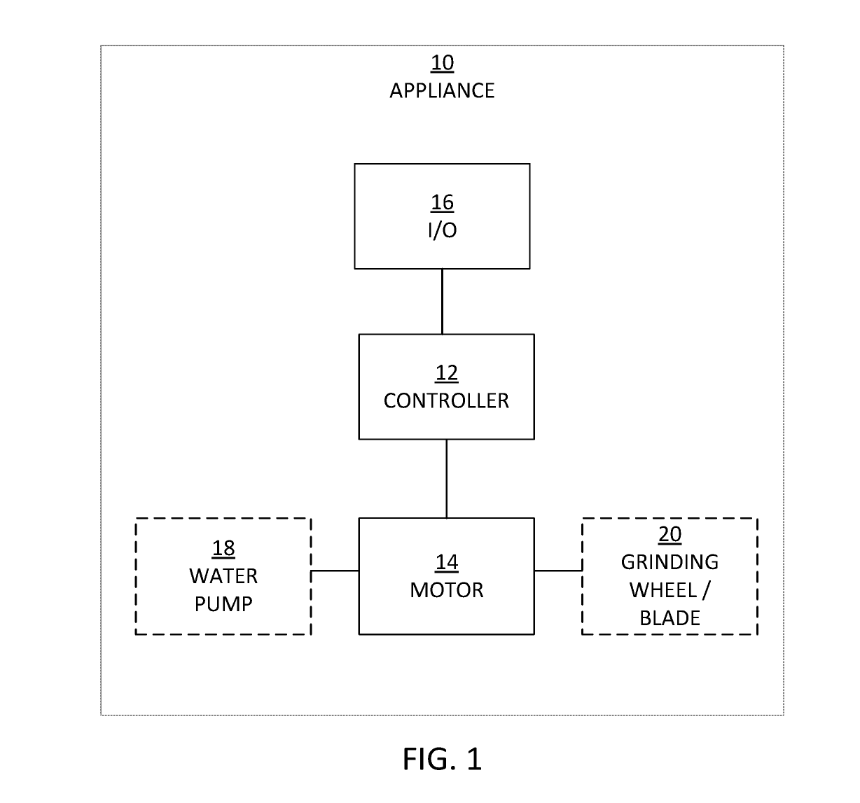

Referring to the drawings in detail, wherein like numerals indicate like elements throughout, FIG. 1 illustrates an appliance in accordance with a preferred embodiment of the present disclosure. Such an appliance may comprise any suitable appliance having a motor that is activated and deactivated during operation of the appliance, and that requires a mechanism for relatively accurately determining when to deactivate the motor. Such an appliance may comprise, for example, a coffee maker or a coffee grinder. The structural aspects of such an appliance of embodiments of the present disclosure are generally the same as for conventional appliances of the same type, and will not be described in detail herein. Rather, the present disclosure will focus on the operational components and procedures that provide the novel mechanism for accurately determining when to deactivate the motor. The appliance 10 of embodiments of the present disclosure comprises a controller 12 for controlling the operation of the appliance 10. The controller 12 may comprise a microprocessor, dedicated or general purpose circuitry (such as an application-specific integrated circuit or a field-programmable gate array), a suitably programmed computing device, or any other suitable means for controlling the operation of the appliance 10. The appliance 10 typically comprises one or more input and/or output devices (I/O) 16, such that the controller 12 receives signal(s) from the input device(s) and sends signals to the output device(s), as conventionally known. The appliance 10 comprises an electric motor 14 (which may be a DC motor or an AC motor). Typically at or near the beginning of an operating cycle (and typically upon receipt of an input signal, such as may be caused by a user pressing a “start” button or the like), the controller 12 activates the electric motor 14. The motor 14 is mechanically connected (directly or via a drive train, which may comprise one or more gears, clutches, etc.) to different components depending on the type of appliance. For example, the motor 14 may be connected to a water pump 18 if the appliance 10 is a coffee maker or to one or more grinding blades or wheels 20 if the appliance 10 is a coffee grinder (the water pump 18 and the grinding blades/wheels 20 are shown in dashed lines as they may or may not be present depending on the type of appliance). When the motor 14 is activated by the controller 12, the water pump 18 pumps water or the grinding blades/wheels 20 rotate to grind coffee beans.

When water is being pumped by the water pump 18, there is a load on the motor 14. When the water tank is empty and water is no longer being pumped, the load on the motor 14 decreases rather abruptly. Somewhat similarly, when coffee beans are being ground by the grinding blades/wheels 20, there is a load on the motor 14. As the coffee beans are being ground and the ground coffee beans drop through a screen, the load on the motor decreases gradually until all of the coffee beans have been ground. Embodiments of the present disclosure use this decreasing motor load to determine when to deactivate the motor.

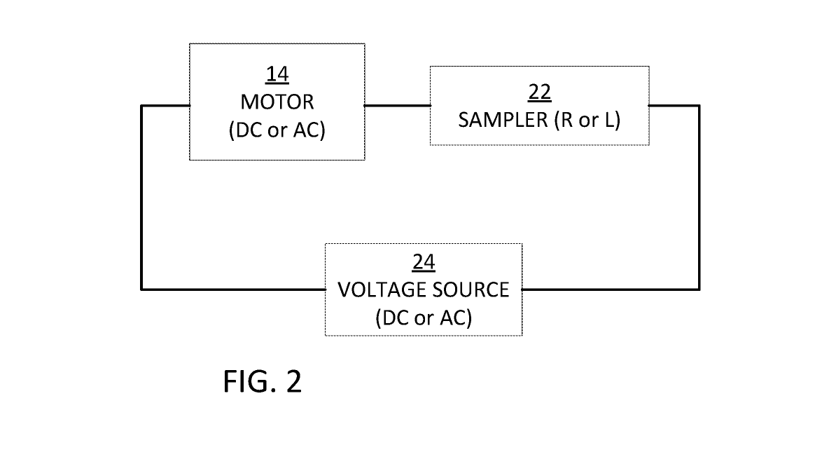

Referring now to FIG. 2, a simplified electrical circuit diagram for a load-sensing circuit to be used in a small appliance is illustrated according to one embodiment of the present disclosure. The circuit of FIG. 2 comprises the motor 14 electrically connected to a voltage source 24 (DC or AC, depending on the motor type) which powers the motor. The voltage source 24 is controllable by the controller 12. The circuit of FIG. 2 further comprises a voltage-sampling component 22 connected in series with the motor 14. Specifically, the voltage-sampling component 22 comprises a resistor (“R”) if the motor 14 is a DC motor or an inductor (“L”) if the motor 14 is an AC motor. Such a voltage-sampling inductor may be the primary coil of a transformer (and the sampled voltage would be measured at the secondary coil). The controller 12 is able to measure the voltage across the resistor or inductor (via an analog-to-digital converter (ADC), for example) and measure the decrease of this voltage during operation of the device. The voltage change across the voltage-sampling component 22 corresponds to the change in the motor load during operation. Thus, the controller is able to determine when to deactivate the motor by measuring the change in the voltage across the voltage-sampling component (resistor or inductor) during operation. The change in the voltage may be a decrease, an increase, or a pattern.

In addition or alternatively to deactivating the motor in response to a change in the detected voltage, the controller may be able to change the amount of electric power supplied to the motor in response to a change in the detected voltage. For example, in a coffee maker a clog may cause a fluid backup and a resulting increase in the load on the motor, and therefore a corresponding change in the detected voltage. To try to prevent a motor overload or other damage to the coffee maker (such as a burst in the hot water chamber), the controller may reduce the electric power to the motor in response to the change in the detected voltage. If the motor load (and detected voltage) continue to increase, the controller may deactivate the motor.

The resistor or the inductor should have a relatively small impedance as compared to the effective impedance of the motor. The impedance of the sampler resistor or inductor should be large enough to provide a measurable voltage decrease across the sampler, but small enough to have little effect on the operation of the circuit. Generally, the ratio of the impedance of the resistor or the inductor to the effective impedance of the motor should be in the range of about 0.1 to about 0.3 (and, in any event, typically less than 0.4).

In one exemplary embodiment of a coffee maker of the present disclosure, the power supply for the motor is ˜12 VDC and the ADC voltage range is 0-5V, such that the sampled voltage should fall roughly between 1-3V for adequate measurement resolution and range. It is desirable to digitize the voltage from the sampler directly without using an amplifier to avoid introducing unwanted noise. In such an exemplary embodiment, the voltage-sampling component comprises a 10-ohm resistor.

As described above, the controller is able to determine when to deactivate the motor or to change the amount of electric power supplied to the motor by measuring the change in the voltage across the voltage-sampling component (resistor or inductor) during operation. This may be accomplished in any one of several suitable ways. For example, the controller may deactivate the motor or change the amount of electric power supplied to the motor if the change in the detected voltage exceeds a predetermined threshold percentage. Alternatively, the controller may deactivate the motor or change the amount of electric power supplied to the motor if the change in the detected voltage exceeds a predetermined threshold amount. As another alternative, the controller may deactivate the motor or change the amount of electric power supplied to the motor if the detected voltage is less than a predetermined threshold voltage (if the voltage is decreasing) or greater than a predetermined threshold voltage (if the voltage is increasing). As yet another alternative, the controller may deactivate the motor or change the amount of electric power supplied to the motor if the change in the detected voltage matches a predetermined pattern.

Typically, in a coffee maker of the present disclosure, the water-running-out event happens in relatively short time and the load change is nearly binary. In one exemplary embodiment of a coffee maker of the present disclosure, a 30% voltage decrease is used as the trigger to deactivate the motor.

Typically, in a coffee grinder of the present disclosure, the motor load decrease (and therefore the sampler voltage change) from a hopper full of coffee beans to an empty hopper is much more gradual than the out-of-water determination for a coffee maker. The ADC curve is a combination of physical factors, such as the random nature of bean types and flow, time dependence of motor internal load, etc. In one exemplary embodiment of a coffee grinder of the present disclosure, the decision to deactivate the motor is made upon a steady relative voltage decrease of 6.7% over four consecutive seconds.

It will be appreciated by those skilled in the art that changes could be made to the embodiments described above without departing from the broad inventive concept thereof. It is understood, therefore, that this disclosure is not limited to the particular embodiments disclosed, but it is intended to cover modifications within the spirit and scope of the present disclosure as defined by the appended claims.

That which is claimed:

1. An appliance comprising:
an electric motor;
a resistor or an inductor in electrical series with the motor; and
a controller;
wherein the controller activates the motor, detects a voltage across the resistor or inductor while the motor is activated, and deactivates the motor or changes an amount of electric power supplied to the motor in response to a change in the detected voltage.

2. The appliance of claim 1, wherein the resistor or the inductor are selected such that a ratio of an impedance of the resistor or the inductor to an impedance of the motor is less than 0.4.

3. The appliance of claim 1, wherein the motor comprises a direct current (DC) motor, and wherein the resistor or inductor comprises a resistor.

4. The appliance of claim 1, wherein the motor comprises an alternating current (AC) motor, and wherein the resistor or inductor comprises an inductor.

5. The appliance of claim 4, wherein the inductor comprises a primary coil of a transformer.

6. The appliance of claim 1, wherein the appliance comprises a coffeemaker and wherein the motor drives a water pump to move water or an air pump to pump air to displace water.

7. The appliance of claim 1, wherein the appliance comprises a coffee grinder and wherein the motor rotates one or more grinding wheels or blades.

8. The appliance of claim 1, wherein the controller deactivates the motor or changes the amount of electric power supplied to the motor if the change in the detected voltage exceeds a predetermined threshold percentage.

9. The appliance of claim 1, wherein the controller deactivates the motor or changes the amount of electric power supplied to the motor if the change in the detected voltage exceeds a predetermined threshold amount.

10. The appliance of claim 1, wherein the controller deactivates the motor or changes the amount of electric power supplied to the motor if the detected voltage is less than or greater than a predetermined threshold voltage.

11. The appliance of claim 1, wherein the controller deactivates the motor or changes the amount of electric power supplied to the motor if the change in the detected voltage matches a predetermined pattern.

12. A method of controlling an electric motor in an appliance, the method comprising:
activating an electric motor;
detecting a voltage across a resistor or an inductor in electrical series with the motor while the motor is activated; and
deactivating the motor or changing an amount of electric power supplied to the motor in response to a change in the detected voltage.

13. The method of claim 12, wherein the resistor or the inductor are selected such that a ratio of an impedance of the resistor or the inductor to an impedance of the motor is less than 0.4.

14. The method of claim 12, wherein the motor comprises a direct current (DC) motor, and wherein the resistor or inductor comprises a resistor.

15. The method of claim 12, wherein the motor comprises an alternating current (AC) motor, and wherein the resistor or inductor comprises an inductor.

16. The method of claim 15, wherein the inductor comprises a primary coil of a transformer.

17. The method of claim 12, wherein the appliance comprises a coffeemaker and wherein the motor drives a water pump to move water or an air pump to pump air to displace water.

18. The method of claim 12, wherein the appliance comprises a coffee grinder and wherein the motor rotates one or more grinding wheels or blades.

19. The method of claim 12, wherein the motor is deactivated or the amount of electric power supplied to the motor is changed if the decrease in the detected voltage exceeds a predetermined threshold percentage.

20. The method of claim 12, wherein the motor is deactivated or the amount of electric power supplied to the motor is changed if the decrease in the detected voltage exceeds a predetermined threshold amount.

21. The method of claim 12, wherein the motor is deactivated or the amount of electric power supplied to the motor is changed if the detected voltage is less than or greater than a predetermined threshold voltage.

22. The method of claim 12, wherein motor is deactivated or the amount of electric power supplied to the motor is changed if the change in the detected voltage matches a predetermined pattern.
